(19) United States
(12) Patent Application Publication
(10) Pub. No.: US 2010/0295142 A1
(43) Pub. Date: Nov. 25, 2010

(54) Optical Element Manufacturing Method, Optical Element, Electronic Apparatus Manufacturing Method, and Electronic Apparatus

(76) Inventor: Takashi Washizu, Tokyo (JP)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/812,218

(22) PCT Filed: Dec. 2, 2008
(86) PCT No.: PCT/JP2008/071865

§ 371 Date: Jul. 8, 2010

(30) Foreign Application Priority Data
Jan. 11, 2008 (JP) 2008-004475

(51) Int. Cl. H01L 31/0232; H01L 31/18

(52) U.S. Cl. 257/432; 438/65; 257/E31.127

(57) ABSTRACT

An optical element manufacturing method wherein change in optical characteristics before and after the reflow process is suppressed, while maintaining excellent transmittance as an optical element. The method is applicable to reflow process wherein an optical apparatus, including an electronic component such as a CCD image sensor (11), is mounted on an electronic apparatus. The method is provided with a step of molding a thermosetting resin, and a step of annealing the molded material in vacuum atmosphere or inert gas atmosphere.

### FIELD OF THE INVENTION

The present invention relates to a method of manufacturing an optical element, an optical element, a method of manufacturing an electrical apparatus and an electrical apparatus, and specifically, relates to a technique suitable for a reflow treatment.

### BACKGROUND OF THE INVENTION

As a constituent material of an optical element to manufacture the optical element with a low cost, plastic has been used. Commonly, a thermoplastic resin has been frequently used, and it has been widely used for an optical element used for an optical apparatus such as an imaging optical apparatus or an optical pickup apparatus. In recent years, in order to further reduce the manufacturing cost of an electronic apparatus having therein an imaging optical apparatus, for example, a mobile phone, a digital camera, or an optical information read/write apparatus, a technology has been proposed, in which a reflow treatment is carried out while electronic parts such as an IC (Integrated Circuits) chip and an optical apparatus including an optical element are placed on a circuit board of an electronic apparatus, on which solder is subjected to potting in advance, whereby the electronic parts and the optical apparatus are simultaneously loaded on the circuit board by melting the solder (for example, refer to Patent Document 1).

Since the reflow treatment is necessary to be carried out under a heating condition in which at least solder can be melted (for example, the maximum temperature is around 260° C.), it is difficult to use a thermoplastic resin which exhibits plasticity when heated. Accordingly, an optical element made of glass having high heat resistance has been commonly used instead of a thermoplastic resin. However, the use of an optical element made of glass increases the manufacturing cost of the optical element itself, whereby the cost reduction effect due to the reflow treatment is diminished. Therefore, application of an optical element made of a thermosetting resin which exhibits high heat resistance while the manufacturing cost is relatively low has been considered.

Patent Document Japanese Patent Application Publication Open to Public Inspection (hereafter referred to as JP-A) No. 2001-24320

### DISCLOSURE OF THE INVENTION

### Problem to be Solved by the Invention

However, when using a thermosetting resin, and thought that that the resin has been fully cured at a constant curing temperature (for example, at around 100° C.), it is rather difficult to complete the curing reaction, and an uncured portion may be partially left in the resin. In a reflow process, an optical element is exposed to an extremely high temperature, although it is only a short time. Accordingly, when an uncured part exists in the molding, the curing reaction is activated by the reflow treatment to proceed the curing reaction at the uncured portion in the reflow process or while it is used after commercialized. As the result, a problem has arisen that a change in the shape or in an optical property such as a refractive index, due to the curing and shrinking, may occur.

Since a reflow process is usually carried out when an optical apparatus is mounted in an electronic apparatus as mentioned above, the spatial relationship of a photo-detector such as a CCD sensor and an optical element such as a lens in an optical apparatus is already fixed in many cases. Moreover, after an optical apparatus is mounted in an electronic apparatus, it becomes still more difficult to carry out a correction process and location correction corresponding to the change of the optical property of the optical apparatus. Therefore, when a location deviation due to the optical performance or deformation of an optical element caused by a reflow treatment occurs, dissolution of the location deviation by tuning of a fixing position is difficult, which may cause a problem of poor reading or an image defect, and, accordingly, the improvement has been desired.

In view of the foregoing problem, the present inventors have tried to heat the optical element (also referred to as an annealing treatment) before the optical apparatus containing the optical element is mounted in an electronic apparatus to substantially complete the curing reaction of the thermosetting resin constituting the optical element. Here, to substantially complete a curing reaction means to cure the optical element to an extent in which the change in the shape or optical property of the optical element before and after the reflow process does not affect the function of the optical apparatus (or the electronic apparatus).

However, in order to fully cure a thermosetting resin, it is necessary to carry out prolonged heating compared with a reflow process at an elevated temperature near the maximum temperature of the reflow process. It was found that a problem occurs in the function of an optical element due to reduction of transmittance of the thermosetting resin caused by the coloration occurs when the optical element is subjected to an annealing treatment. On the other hand, since the thermosetting resin which can be used as a material of an optical element is limited according to the desired optical property such as a refractive index or a dispersion property, it was difficult to improve the property of the thermosetting resin itself.

Therefore, a major object of the present invention is to provide a method of manufacturing an optical element in which the change in the shape and the optical property before and after a reflow process is suppressed, whereby the transmittance of the optical element is not reduced (as well as to provide an optical element manufactured by the method).

Another object of the present invention is to provide a method of manufacturing an optical apparatus equipped with an optical apparatus containing such an optical element (as well as to provide an optical apparatus manufactured by the method).

### Means to Solve the Problem

According to one aspect of the present invention, provided is a method of manufacturing an optical element comprising,
a step of forming the optical element by setting to mold a thermosetting resin, and
a step of annealing the optical element in a vacuum atmosphere or an inert gas atmosphere.

According to another aspect of the present invention, a method of manufacturing an electronic apparatus comprising,
a step of forming an optical element by setting to mold a thermosetting resin;
a step of installing the optical element in an optical apparatus; and
a step of placing the optical apparatus on a circuit board of an electronic apparatus followed by reflowing the electronic apparatus,
   wherein the method comprises a step of annealing the optical element at a point in time after forming the optical element and before the above reflowing treatment.

### EFFECTS OF THE INVENTION

According to the present invention, by annealing a molding under vacuum or in an inert gas atmosphere, the change in the optical property before and after a reflow process can be suppressed as well as the reduction of the transmittance of the optical element due to annealing can be suppressed. As the result of a further consideration, what is surprising is that, by annealing the optical element, the birefringence which is thought to be originated from the distortion caused in the molding process of the optical element is reduced

### BRIEF DESCRIPTION OF THE DRAWING

FIG. 1 is a schematic oblique view of an electronic apparatus equipped with an imaging module used in a preferable embodiment of the present invention.

FIG. 2 is a schematic cross-sectional view of a partly enlarged imaging module in an electronic apparatus used in a preferable embodiment of this invention.

FIGS. 3a-3c schematically illustrate a method of manufacturing an electronic apparatus equipped with an imaging module used in a preferable embodiment of the present invention.

### DESCRIPTION OF SYMBOLS

100 Electronic apparatus (equipped with an imaging module)
1 Circuit board
2 Imaging module
3 Cover case
4 Imaging opening
5 Substrate module
6 Lens module
10 Subsidiary substrate
10a Mounting hole
11 CCD image sensor
12 Resin
15 Lens case
15a Holder portion
15b Mount portion
16 Lens
17 Collar parts
18 Conductive material

### BEST MODES TO PRACTICE THE INVENTION

Preferable embodiments of the present invention will be described by referring to drawings.

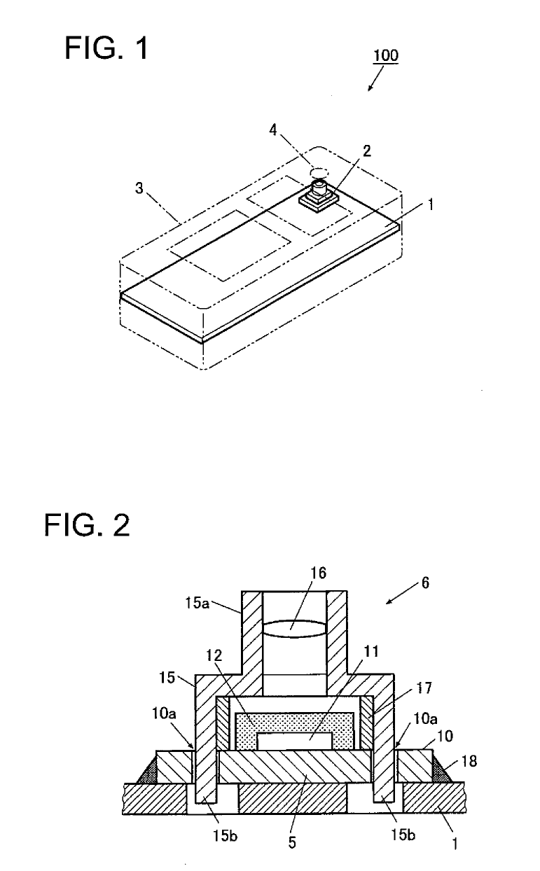

As shown in FIG. 1, electronic apparatus 100 has circuit board 1 on which electronic parts composing an electronic circuit for a mobile information terminal such as a mobile phone are mounted. On circuit board 1, imaging module 2 as one of examples of optical apparatuses is mounted. Imaging module 2 is a small camera used for board mounting, which is composed of a CCD image sensor and a lens in combination, and can take in an image of an imaging objective through imaging opening 4 provided in cover case 3 in a finished product in which circuit board 1 on which electronic parts are mounted is incorporated in the cover case 3.

Electronic parts other than imaging module 2 are not shown in FIG. 1. Imaging module 2 may be one having a CMOS image sensor and a lens in combination.

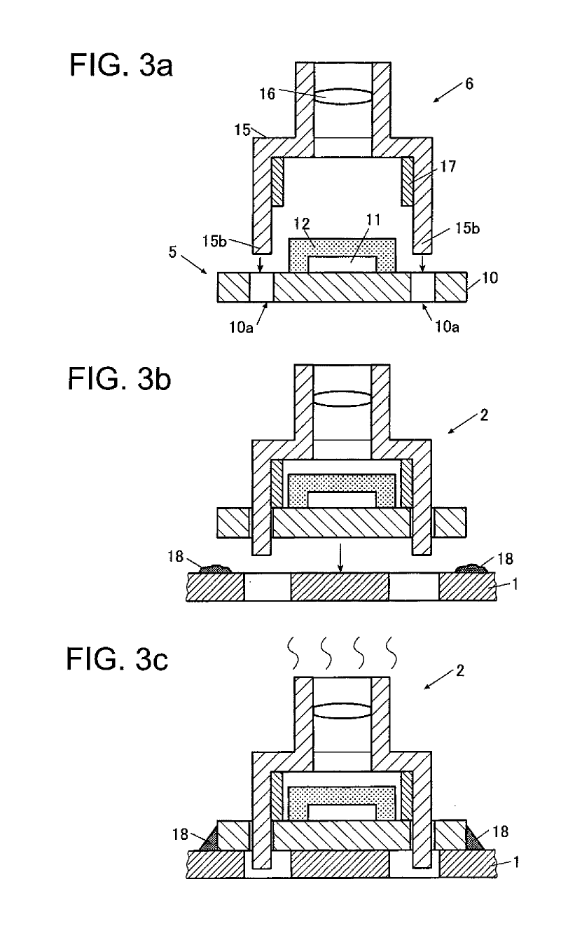

Imaging module 2 is composed of substrate module 5 (refer to FIG. 3a) and lens module 6 (refer to FIG. 3a) as shown in FIG. 2, and imaging module 2 as a whole is mounted on circuit board 1 by mounting substrate module 5 on circuit board 1. Substrate module 5 is a photo receiving module containing subsidiary substrate 10 on which a photo receiving element for image formation, CCD image sensor 11, is mounted, and an upper surface of CCD image sensor 11 is sealed with resin 12.

A photo receiving part (not illustrated in the drawing) in which many photoelectric conversion pixels are arranged in lattice form is formed on upper surface of CCD image sensor 11. Charge generated on each pixel by focusing an optical image on the photo receiving part is taken out as image signal. Subsidiary substrate 10 is mounted on circuit board 1 with a conductive material 18 such as solder 18, whereby subsidiary substrate 10 is fixed on circuit board 1, as well as connecting electrodes (not shown) on subsidiary substrate 10 are electrically connected to circuit electrodes (not shown) on the upper surface of circuit board 1.

Lens module 6 has lens holder 15 to hold lens 16. Lens 16 is held by lens holder 15 at upper portion and the upper portion is holder portion 15a to hold lens 16. Bottom portion of lens holder 15 is mounting portion 15b which fixes lens module 6 on subsidiary substrate 10 by being inserted into mounting hole 10a provided in subsidiary substrate 10. Lens module may be fixed by employing a method of inserting mounting portion 15 into mounting hole 10a with pressure, or by employing a method of adhering by using an adhesive.

Lens 16 is one of the examples of an optical element of the present invention, and composed of a thermosetting resin. As a thermosetting resin, for example, the resins listed below may be preferably used.

### [Thermosetting Resin]

The thermosetting resin is not specifically limited as far as it is a curable resin which is cured by a heat treatment, however, as the thermosetting resin, for example, those listed in following (1)-(4) may be preferably used.

### (1) Silicone Resins

A silicone resin having a siloxane bond containing Si—O—Si as a main chain may be used. As the silicone resin, one containing a prescribed amount of polyorganosiloxane is usable (for example, refer to JP-A No. 6-9937).

The polyorganosiloxane resin is not specifically limited provided that the resin forms a three dimensional network structure via a siloxane bonding moiety by a polymerization reaction via continuous hydrolysis/dehydration-condensation by healing. The polyorganosiloxane resin generally exhibits a setting property by a long term and high temperature beating, and it has a characteristic that, when it is once cured, it hardly becomes softened by heating.

Such a polyorganosiloxane resin contains following Foy mula (A) as a constituting unit, and its form is any of a chain, a ring, or a network form.

((R₁₎(R₂)SiO)ₙ (A)

In Formula (A), “R₁” and “R₂” each represent substituted or unsubstituted univalent hydrocarbon group which may be the same or different. Examples of “R₁” and “R₂” include: an alkyl group such as a methyl group, an ethyl group, a propyl group, or a butyl group, an alkenyl group such as a vinyl group or an allyl group, an aryl group such as a phenyl group or a tolyl group, and a cycloalkyl group such as a cyclohexyl group or a cyclooctyl group; and groups wherein hydrogen atoms bonded to carbon atoms of these groups are replaced by a halogen atom, a cyano group, or an amino group, including, for example, a chloromethyl group, a 3,3,3-trifluoropropyl group, a cyanomethyl group, a γ-aminopropyl group, and an N-(β-aminoethyl)-γ-aminopropyl group. The groups represented by “R₁” and “R₂” each may be also a group selected from a hydroxyl group and an alkoxy group. Further, in above Formula (A), “n” represents an integer of 50 or more.

Polyorganosiloxane resins are commonly used via dissolution in a hydrocarbon based solvent such as toluene, xylene, or petroleum based solvent; or in a mixture of any of these and a polar solvent Further, solvents of different compositions may be used in combination, provided that these are mutually soluble.

The production method of a polyorganosiloxane resin is not specifically limited, and any of the methods known in the art are employable. For example, one type of organohalogenosilane or a mixture of two or more types of organohalogenosilanes is subjected to hydrolysis or alcoholysis to obtain the resin. A polyorganosiloxane resin generally contains a hydrolyzable group such as a silanol group or an alkoxy group. These groups are contained at a ratio of 1 to 10% by mass converted as a silanol group equivalent.

These reactions are commonly conducted in the presence of a solvent capable of dissolving an organohalogenosilane. Further, there is usable a method of synthesizing a block copolymer wherein a straight-chain polyorganosiloxane having a hydroxyl group, an alkoxy group, or a halogen atom at molecular chain terminals is hydrolyzed together with organotrichlorosilane. Thus-prepared polyorganosiloxane resin usually contains residual HCl, and those containing at a ratio of at most 10 ppm, preferably at most 1 ppm, may be used in view of good storage stability in a composition of the embodiment of the present invention.

### (2) Acrylic Resins

Specific examples of an acrylic resin include: an acryl resin having a tricycle cyclodecane derivative (refer to JP-A Nos. 7-26193 and 7-69985), NK ester DCP (tricyclodecane dimethanol dimethacrylate) produced by SHIN-NAKAMURA CHEMICAL, Co., Ltd., NK ester A-DCP produced by SHIN-NAKAMURA CHEMICAL, Co., Ltd., adamantyl (meth)acrylate (refer to JP-A No. 2005-8527), NK ester IB produced by SHIN-NAKAMURA CHEMICAL, Co., Ltd., NK ester A-IB produced by SHIN-NAKAMURA CHEMICAL, Co., Ltd., 1,3-adamantine dial diacrylate, 1,3,5-adamantane triol triacrylate, and adamantyl (meth)acrylate (refer to JP-A No. 2005-8527).

These acryl resins may be polymerized independently. In such cases, 0.01-5 parts by mass of the following polymerization initiator based on 100 parts by mass of whole monomer is used. Further, in order to increase a degree of cross linking, the following cross-linkable monomer may be mixed with an above (meth)acrylate. In such a case, it is preferable that 60-5% by mass of cross-linkable monomer is mixed with 40-95% by mass of (meth)acrylate together with a polymerization initiator.

Examples of a cross-linkable monomer include: methyl(meth)acrylate, benzyl(meth)acrylate, phenyl(meth)acrylate, ethylene glycol (meth)acrylate, diethylene glycol (meth)acrylate, triethylene glycol (meth)acrylate, tetraethylene glycol di(meth)acrylate, 2-methyl-1,8-octanediol (meth)acrylate, 1,6-hexanediol di(meth)acrylate, neopentyldiol di(meth)acrylate, polyethylene glycol di(meth)acrylate, ethylene oxide modified bisphenol A di(meth)acrylate, propylene oxide modified bisphenol A di(meth)acrylate, trimethylol propane tri(meth)acrylate, ditrimethylol propane tetra(meth)acrylate. These cross-linkable monomers may be used alone or in combination of two or more kinds.

The initiation of polymerization may be conducted by using radical polymerization initiators such as various peroxide and azo compounds.

The radical polymerization initiator is not specifically limited and well known initiators are usable. Examples of typical radical polymerization initiators include: ketone peroxides, dialkyl peroxides, peroxyketals, peroxycarbonates, hydroperoxides, peroxyesters and diacyl peroxides. Further, there can be cited azo compounds such as 2,2′-azobis isobutyronitrile, 2,2′-azobis(4-dimethylvaleronitrile), 2,2′-azobis(2-methyl butyronitrile) and 1,1′-azobis(cyclohexane-1-carbonitrile).

Further, a setting accelerator is incorporated, if needed. The setting accelerator is not specifically limited as far as it exhibits good setting property and causes no coloration nor deterioration of transparency of the thermosetting resin, however, for example, imidazoles such as 2-ethyl-4-methylimidazole (2E4MZ), a tertiary amine, a quarternary ammonium salt, bicyclic amidines such as diazabicyclo undecyne and derivatives thereof, a phosphine and a phosphonium salt are usable. These compounds may be used alone or in combination of two or more kinds.

### (3) Resins Containing an Allyl Ester Compound

Preferable examples include: a bromine-containing (meth)allyl ester which does not contain an aromatic ring (refer to JP-A No. 2003-66201), allyl (meth)acrylate (refer to JP-A No. 5-286896), an allyl ester resin (refer to JP-A No. 5-286896 or JP-A No. 2003-66201), a copolymerization compound of an acrylic ester and an epoxy group-containing unsaturated compound (refer to JP-A No. 2003-128725), an acrylate compound (refer to JP-A No. 2003-147072) and an acrylic ester compound (refer to JP-A No. 2005-2064).

### (4) Epoxy Resins

As epoxy compounds, there can be listed, for example, a novolac phenol type epoxy resin, a biphenyl type epoxy resin, a dicyclopentadiene type epoxy resin, a bisphenol F diglycidyl ether, a bisphenol A diglycidyl ether, 2,2′-bis(4-glycidyloxycyclohexyl)propane, 3,4-epoxycyclohexylmethyl-3,4-epoxycyclohexane carboxylase, vinylcyclohexene dioxide, 2-(3,4-epoxycyclohexyl)-5,5-spiro-(3,4-epoxycyclohexane)-1,3-dioxane, bis(3,4-epoxycyclohexyl) adipate, 1,2-cyclopropane dicarboxylic acid bisglycidyl ester, triglycidyl isocyanurate, monoallyldiglycidyl isocyanurate, and diallylmonoglycidyl isocyanurate.

As a hardener, an acid anhydride hardener and a phenol hardener are preferably usable. Specific examples of acid anhydride hardeners include phthalic anhydride, maleic anhydride, trimellitic anhydride, pyromellitic anhydride, hexahydrophthalic anhydride, 3-methyl-hexahydrophthalic anhydride, 4-methyl-hexahydrophthalic anhydride, a mixture of 3-methyl-hexahydrophthalic anhydride and 4-methyl-hexahydrophthalic anhydride, tetrahydrophthalic anhydride, nadic anhydride, and methylnadic anhydride. A hardening accelerator is optionally contained if appropriate. Hardening accelerators are not specifically limited provided that these accelerators exhibit excellent hardening performance and are colorless, as well as not losing transparency of a thermosetting resin. Usable are, for example, imidazoles such as 2-ethyl-4-methylimidazole (2E4MZ), a tertiary amine, a quaternary ammonium salt, bicyclic amidines such as diazabicycloundecene and derivatives thereof, phosphine, and a phosphonium salt. These may be used alone or in combination of at least 2 types thereof.

Before imaging module 2 is mounted on circuit board 1 via a reflow process, an annealing treatment of lens 16 which is one example of the optical element of the present invention is carried out beforehand. “An annealing treatment” means a heat treatment for certain duration or a moisture-heat processing at a constant temperature after shaping. The annealing temperature is preferably in the range of −100° C. to +50° C. with respect to the reflow temperature. For example, if the reflow temperature is 250° C., the annealing temperature is 150-300 degrees C. The duration of annealing is preferably 1 hour or more, and more preferably 1 hour or more but 5 hours or less.

Subsequently, a manufacturing method of electronic apparatus 100 according will be described by referring to FIG. 3.

First, a thermosetting resin is injected and filled a prescribed mold to thermally set the resin, whereby a molding composed of a thermosetting resin is formed. Then, the molding is accommodated in a prescribed constant temperature oven, and the molding is subjected to a heat treatment or a heat-moisture treatment (annealing) at a constant temperature for a certain duration (for example, at 260° C. for one hour), while the constant temperature oven is evacuated to vacuum or filled with an inert gas.

In other to form a vacuum atmosphere, the oven may be evacuated down to 6.7×10⁻¹ using an oil-sealed rotary pump produced by vacuum drying oven ULVAC, Inc. In order to form an inert atmosphere, for example, N₂ and Ar are usable.

After lens 16 is prepared, substrate module 5 and lens module 6 are assembled. Mount portion 15b of lens holder 15 is inserted and fixed in mounting hole 10a of subsidiary substrate 10, so that bottom end of preliminarily mounted collar parts 17 in lens holder 15 comes into contact with top face of subsidiary substrate 10, whereby imaging module 2 is formed, as shown in FIG. 3(a).

In the present embodiment, an annealing treatment is carried out before lens 16 is installed in lens module 6. However, the annealing treatment may be carried out at any time before imaging module 2 which is an optical apparatus is mounted on circuit board 1 of the electronic apparatus 1. Accordingly, the annealing treatment may be carried out after lens 16 is installed in lens module 6 or may be carried out on imaging module 2 after lens module 6 is set on subsidiary substrate 10.

When, an annealing treatment is carried out on imaging module 2, it is difficult to respond to the change in shape or optical property of lens 16 by annealing, since the locational relationship between lens 16 and CCD image sensor 11 is already fixed Accordingly, the annealing treatment is preferably carried out before lens module 6 is installed in imaging module 2.

Then, imaging module 2 and other electronic parts are placed on predetermined mounting position on circuit board 1 having preliminarily provided (potted) conductive material 18 such as solder as shown in FIG. 3(b). Thereafter, circuit board 1 on which imaging module 2 and other electronic parts are placed is conveyed to a reflow furnace (not shown) by such as a belt conveyer, and the circuit board 1 is heated (reflow treatment) at a temperature of 230-270° C. for 5-10 minutes as shown in FIG. 3(c). The “reflow treatment” is almost the same treatment as the annealing treatment of the molding of lens 16 in regard to heating. However, it is a treatment to melt conductive material 18 such as a solder, and the purpose is different from the purpose of annealing. As the result of the reflow treatment, conductive material 18 is melted, and imaging module 2 is mounted on circuit board 1 together with other electronic parts.

In the present embodiment as described above, since the molding of lens 16 is annealed under vacuum or in an inert gas atmosphere, the reduction of light transmittance of an optical element due to the annealing treatment and the change in shape or optical property of an optical element before and after the reflow treatment can be suppressed.

### EXAMPLES

### 1 Sample Preparation

### 1.1 Preparation Offenses 1-11

Into NK ester DCP (tricyclodecane dimethanol dimethacrylate) produced by SHIN-NAKAMURA CHEMICAL, Ca, Ltd., 1% by mass of Perbutyl 0 produced by NOF Corporation as a polymerization initiator was added, and the mixture was allowed to be set at 150° C. for 10 minutes to prepare 11 lenses. The design values of the lenses are shown in Table 1 as lens data wherein
f: focal distance of a lens
Fno: F number
2Y: diagonal length of an image plane
nd: refractive index of a lens at d line
vd: Abbe's number of a lens at d line

The aspheric shape is defined as follows. Namely, when x represents a distance from a tangent plane along the optical axis (also referred to as a sag), y represents a height from the optical axis, r represents an approximated curvature radius, K represents a conic constant, and Aₙ (n=4, 6, 8, 10, 12) represents an aspheric constant of n-th degree, xis is expressed by the following mathematical equation, “Equation 1”.

$$x = \frac{{y}^{2} / r}{1 + \sqrt{1 - ( 1 + K ) {y}^{2} / {r}^{2}}} + \sum {A}_{n} {y}^{n} \qquad Equation 1$$

Further, ten's power (for example, 2.5×10⁻³) is expressed by using E (for example, 2.5E-3).

TABLE 1
Lens Data
f = 2.26 mm Fno = 3.29 2Y = 2.56 mm

| Surface | | | | | |
|---|---|---|---|---|---|
| number | Curvature radius | Interval | Glass material | nd | νd |
| OBJ | — | 300.050 | — | | |
| STO | INFINITY | 0.380 | — | | |
| 2(*) | 1.5016 | 1.100 | Settable resin | 1.52676 | 53.7 |
| | | | material | | |
| 3(*) | −4.3233 | 0.200 | — | | |
| 4 | INFINITY | 0.300 | BK7 | 1.51680 | 64.2 |
| 5 | INFINITY | 1.221 | — | | |
| 6 | INFINITY | — | — | | |

Aspheric surface data

| Aspherical coefficient | Second surface | Third surface |
|---|---|---|
| k | 8.8212E−01 | 1.9176E+01 |
| A4 | 6.8973E−02 | 1.1229E−01 |
| A6 | 1.1482E+00 | 1.4290E+00 |
| A8 | −1.1101E+01 | −5.5438E+00 |
| A10 | 3.7395E+01 | 1.0700E+01 |
| A12 | −4.3804E+01 | −7.8580E+00 |

One of the 11 lenses was designated as lens 1 as it was, and the other 10 lenses were subjected to annealing treatments (heat treatments) under atmospheres of air, vacuum or N₂ as described in Table 2 to obtain lenses 2-11.

### 1.2 Preparation of Lenses 12-18

According to a method disclosed in JP-A No. 2002-193883, 2-alkyl 2-adamantyl (meth)acrylate was prepared, which was set at 130° C. for 10 minutes to prepare 7 lenses. The design values of the lenses were the same as those listed in Table 1. One of the 7 lenses was designated as lens 12 as it was, and the other 6 lenses were subjected to annealing treatments (heat treatments) under atmospheres of air, vacuum or N₂ as described in Table 2 to obtain lenses 13-18.

### 1.3 Preparation of Lenses 19-22

Each equivalent of an aromatic-containing epoxy resin produced by DAICEL CHEMICAL INDUSTRIES, LTD. and an acid anhydride EPICLON B-650 produced by Dainippon Ink & Chemicals, Inc. as a hardener were mixed, and the mixture was then set at 160° C. for 10 minutes to prepare 4 lenses. The design values of the lenses were the same as those listed in Table 1. One of the 4 lenses was designated as lens 19 as it was, and the other 3 lenses were subjected to annealing treatments (heat treatments) at 260° C. for 1 hour under atmospheres of air, vacuum or N₂ to obtain lenses 20-22, respectively.

### 2 Evaluation of Sample

### 2.1 Transmittance

On lenses 2-11, 13-18, 20-22, transmittances at a wavelength of 400 nm of the lenses before annealing and those of the lenses after annealing were measured by using a transmittance meter (U-4100 produced by HITACHI Ltd.), and the changes (%) of the transmittances after annealing with respect to those before annealing were calculated. The results of the calculations were shown in Table

2. The Evaluation Criteria A, B and C in Table 2 were as Follows:
A: less than 3%;
B: 3% or more but less than 5%; and
C 5% or more

### 2.2 Modulation Transfer Function Floating

By using an MTF meter MATRIX-PLUS produced by NANOTEX Corp., the MTF value of each of lenses 1-12 at a spatial frequency of 78 lp/mm was determined using d line. Thereafter, each of lenses 1-12 was accommodated in a 260° C. furnace and left for 10 minutes (hypothetical reflow treatment). On each of lenses 1-12 after the hypothetical reflow treatment, the MTF value was measured in a similar manner, and the change in the MTF value before and after the reflow treatment was calculated. An MTF value (abbreviation of a Modulation Transfer Function value) is an evaluation method of a lens using a ratio of contrast reproduction, and this value is commonly used for the evaluation of the property of an optical lens. Here, the change in the optical property caused by the change of characteristics such as the shape change of an optical element or the change in refractive index is totally evaluated as the change in the MTF value. The results of the calculations were shown in Table 2. In Table 2, the amounts of changes of lenses 2-12 were expressed as relative values when the amount of change of lens 1 was set to 1.0, the amounts of changes of lenses 13-18 were expressed as relative values when the amount of change of lens 13 was set to 1.0, and the amounts of changes of lenses 20-22 were expressed as relative values when the amount of change of lens 19 was set to 1.0.

### 2.3 Birefringence

On lenses 1-22, the extents in the reduction of birefringence were determined by using a Senarmont meter, while the birefringence of lenses before the anneal treatments were set to 100%. The observation results were shown in Table 2. The evaluation criteria A, B and C in Table 2 were as follows:
A: 50% or more;
B: 30% or more but less than 50%; and
C: less than 30%.

In the present invention, the reduction of birefringence is not essential, however, it is preferable to reduce the birefringence.

TABLE 2

| | Annealing treatment | | | | | MTF | |
|---|---|---|---|---|---|---|---|
| | Conducted | | | | | change | |
| Sample | or | | Temperature | Duration | Transmittance | (relative | |
| (Lens) | not conducted | Atmosphere | (° C.) | (hour) | change | value) | Birefringence |
| 1 | not conducted | — | — | — | — | 1.00 | C |
| 2 | conducted | Air | 260 | 1 | C | 0.78 | C |
| 3 | | Vacuum | | | A | 0.57 | A |
| 4 | | N₂ | | | A | 0.59 | A |
| 5 | | Vacuum | 330 | | B | 0.70 | A |
| 6 | | | 130 | | A | 0.80 | C |
| 7 | | | 260 | 0.5 | A | 0.72 | B |
| 8 | | | 300 | 1 | A | 0.60 | A |
| 9 | | | 170 | 1 | A | 0.65 | B |
| 10 | | | 260 | 4 | A | 0.56 | A |
| 11 | | | 260 | 6 | B | 0.75 | A |
| 12 | not conducted | — | — | — | — | 1.00 | C |
| 13 | conducted | Air | 260 | 1 | C | 0.85 | C |
| 14 | | Vacuum | | | A | 0.60 | A |
| 15 | | N₂ | | | A | 0.61 | A |
| 16 | | Vacuum | 330 | | B | 0.72 | A |
| 17 | | | 130 | | A | 0.81 | C |
| 18 | | | 260 | 0.5 | A | 0.74 | B |
| 19 | not conducted | — | — | — | — | 1.00 | C |
| 20 | conducted | Air | 260 | 1 | C | 0.82 | C |
| 21 | | Vacuum | | | A | 0.64 | A |
| 22 | | N₂ | | | A | 0.64 | A |

### 3 Conclusion

As shown in Table 2, lenses 3 and 4, and lenses 8-10 gave excellent results when lenses 3-11 were compared with lenses 1 and 2, describing that, when the annealing treatments were carried out under a vacuum atmosphere or an inert gas atmosphere, the changes in transmittance and MTF value were suppressed and that such treatments were effective to suppress the change in optical property before and after a reflow treatment. In lenses 5 and 6, reduction of transmittance and birefringence were remained because the annealing temperatures were not appropriate. In lens 7, the effect was small because the duration of treatment was short. It is clear that, in lens 11, reduction of transmittance occurred because the duration of treatment was too long. From the above results, it is clear that, as annealing conditions, an annealing temperature of −100° C. to +50° C. with respect to the reflow temperature and the annealing duration of 1-5 hours are preferable. It is also clear that lenses 12-18 and lenses 19-22 showed the same tendencies as those of lenses 1-11.

1. A method of manufacturing an optical element for an optical apparatus, the optical apparatus being able to be subjected to a reflow process for mounting the optical apparatus on a circuit board of an electronic apparatus, and the method comprising the steps of:
forming the optical element by setting a thermosetting resin; and
annealing the optical element under vacuum or in an inert gas atmosphere.

2. The method of claim 1, wherein an annealing temperature is in the range of −100° C. to +50° C. of a temperature of the reflow treatment.

3. The method of claim 2, wherein duration of annealing is 1 to 5 hours.

4. The optical element manufactured by a the method of claim 1.

5. A method of manufacturing an electronic apparatus comprising the steps of:
forming an optical element by setting to mold a thermosetting resin;
installing the optical element in an optical apparatus; and
mounting the optical apparatus on a circuit board of an electronic apparatus followed by reflowing the electronic apparatus,
wherein the method comprises a step of annealing the optical element at a point in time after forming the optical element and before reflowing the electronic apparatus.

6. The method of claim 5, wherein an annealing temperature is in the range of −100° C. to +50° C. of a temperature of the reflow treatment.

7. The method of claim 6, wherein duration of annealing is 1 hour or more.

8. The electronic apparatus manufactured by the method of claim 5.
